(19) United States
(12) Patent Application Publication
(10) Pub. No.: US 2004/0097257 A1
(43) Pub. Date: May 20, 2004

(54) Portable computer and method for providing wireless network accessibility status

(75) Inventor: Youne-sang Lee, Suwon City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., ltd., Suwon-city (KR)

(21) Appl. No.: 10/690,609

(22) Filed: Oct. 23, 2003

(30) Foreign Application Priority Data
Nov. 14, 2002 (KR) 2002-70630

(51) Int. Cl. G06F 1/16; H05K 7/00; H04M 1/00

(52) U.S. Cl. 455/550.1; 455/562.1; 455/557; 455/434; 455/572; 361/683

(57) ABSTRACT

A portable computer has a wireless communication part receiving and transmitting a wireless signal through a wireless communication service network, a displaying part, and a selection part to select whether to display a wireless accessibility to the wireless service network. A BIOS memory stores a network accessing routine determining the wireless accessibility based on the wireless signal received by the wireless communicating part. A controller controls a power supplying part to supply power to the displaying part, the wireless communication part and the BIOS memory, thereby executing the network accessing routine, while the power to the portable computer is turned off, to provide the wireless accessibility, for example, by displaying it in the displaying part, according to the selection to display the wireless accessibility. The availability for connecting to the wireless service network can be ascertained before the O/S booting, while the system power is turned off.

### CROSS-REFERENCE TO RELATED APPLICATIONS

This application claims the benefit of Korean Patent Application No. 2002-70630, filed Nov. 14, 2002, in the Korean Intellectual Property Office, the disclosure of which is incorporated herein by reference.

### BACKGROUND OF THE INVENTION

1. Field of the Invention

The present invention relates, in general, to a portable computer and a method for controlling the portable computer, and more particularly, to a portable computer comprising a wireless communication part receiving and transmitting a wireless signal through a wireless communication service network and providing a wireless network accessibility status, and a method of controlling the portable computer.

2. Description of the Related Art

Different from a desktop computer, portability and simplicity are important in a portable computer. In addition, the portable computer needs to employ sufficient functions to substitute the desktop computer. The portable computer mentioned above is a collective reference to a laptop computer, a notebook computer and a palmtop computer, etc., as far as they are portable. The portable computer can be advantageous to carry if it can be used as a portable terminal wirelessly accessing a network for data communication without regard to location.

The wireless networking employed in the portable computer can be conducted by a connection of a wireless LAN card to a PCMCIA (Personal Computer Memory Card International Association) standard I/O port for the portable computer, or by installation of a BlueTooth module for local area wireless communication using an electric wave, etc. Through these methods, the user can be supplied with the services provided through the wireless communication service network.

However, the portable computer employing such methods of wireless networking is limited with regard to the distance within which use of the wireless communication service network is available, and thus, the user is requested (required) to locate to a position within which access to the wireless communication service network is available. For this purpose, the user executes a wireless LAN utility program. By executing the wireless LAN utility program at an operating system (O/S) level, which requires turning on the power to the portable computer and completing a POST booting and the O/S booting, it is possible to ascertain whether access to the wireless communication service network is available.

However, as described above, determining whether the conventional portable computer can wirelessly connect to a network is only possible when the computer system is in a ready operational state after the O/S booting, thereby increasing power consumption.

### SUMMARY OF THE INVENTION

Accordingly, the present invention provides a portable computer wherein an accessibility to a wireless service network can be ascertained before an O/S booting, while the system power is turned off, thereby reducing power consumption, and a method of controlling the portable computer.

Additional aspects and advantages of the invention will be set forth in part in the description which follows and, in part, will be obvious from the following description, or may be learned by practice of the invention.

The present invention may be achieved by providing a portable computer including a power supplying part and a wireless communication part receiving and transmitting a wireless signal through a wireless communication service network, the portable computer comprising a displaying part; a selection part to select whether to display an accessibility to the wireless service network; a BIOS memory storing therein a network accessing routine determining the accessibility to the wireless communication service network based on the wireless signal received through the wireless communicating unit; and a controller controlling the power supplying part to allow the power supplying part to supply power to the displaying part, the wireless communication part and the BIOS memory, executing the network accessing routine, and controlling the display part to display the accessibility in the displaying part according to a selection to display the accessibility through the selection part while the power is turned off.

According to an aspect of the present invention, if determined that a predetermined period of time has passed since displaying the accessibility was selected through the selection part, the controller controls the power supplying part to interrupt power supply to the displaying part, the wireless communication part and the BIOS memory.

The present invention may be also achieved by providing a method of controlling a portable computer including a power supplying part and a wireless communication part receiving and transmitting a wireless signal through a wireless communication service network, the method comprising storing in a BIOS memory beforehand a network accessing routine determining an accessibility to the wireless service network based on the wireless signal received through the wireless communication part; selecting to display the accessibility to the wireless service network while power is turned off; supplying the power to the displaying part, the wireless communication part, and the BIOS memory from the power supplying part, according to the selecting; executing the network accessing routine of the BIOS memory; and displaying the accessibility to the wireless service network as a result of executing the network accessing routine.

According to an aspect of the present invention, the method further comprises controlling the power supplying part to interrupt the power supply to the displaying part, the wireless communication part and the BIOS memory, if determined that a predetermined period of time has passed since displaying the accessibility was selected through the selection part.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 is a control block diagram of a portable computer, according to an embodiment of the present invention;

FIG. 2 is a control block diagram of a portable computer, according to another embodiment of the present invention; and

FIG. 3 is a flow chart of controlling the portable computers shown in FIGS. 1 and 2, according to an embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

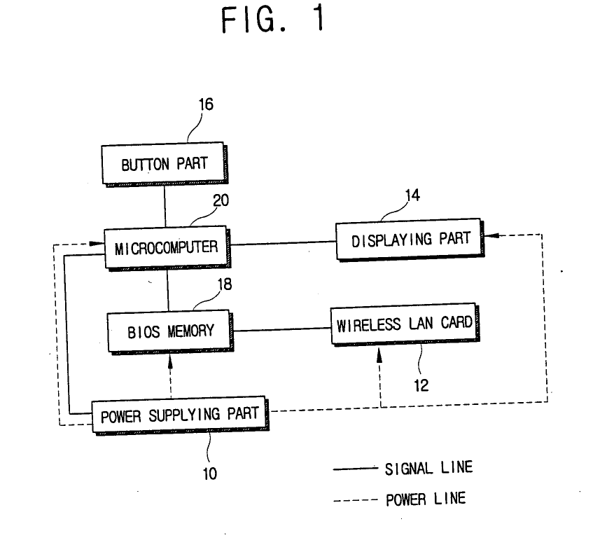

FIG. 1 is a control block diagram of a portable computer, according to an embodiment of the present invention. In FIG. 1, the portable computer comprises a power supplying part 10, such as an adapter or a battery, supplying power to the portable computer system, a wireless LAN card 12 receiving and transmitting a wireless signal through a wireless communication service network, a BIOS memory 18 storing therein a network accessing routine ascertaining the accessibility to the wireless service network, a displaying part 14 displaying thereon a result of executing the network accessing routine of the BIOS memory, a button part 16 allowing the user to select whether to display the accessibility to the wireless service network, and a microcomputer 20 supplying the power to some of the portable computer system components to execute the network accessing routine, according to a selection to display the accessibility to the wireless service network through the button part 16 while the system power is turned off.

The wireless LAN card 12, as a card for wireless network interface, periodically receives a signal supplied from an access point connected to a server and checks an environment for access to the wireless network to ascertain whether the wireless network service is available. That is, typically, the wireless LAN card 12 analyzes whether the signal level received through an antenna provided in the wireless LAN card 12 is within an accessible wireless service frequency band and determines whether the portable computer can access the wireless service network (i.e., wirelessly access a network).

The BIOS memory 18 stores therein a network accessing routine determining whether the portable computer is accessible to the wireless service network, based on the wireless signal received and analyzed by the wireless LAN card 12. The network accessing routine is executed by a control signal of the microcomputer 20 (to be described later). The accessibility to the wireless service network comprises a sensitivity of the wireless signal.

According to an aspect of the present invention, the displaying part 14 comprises an LED. The displaying part 14 displays whether the portable computer is accessible to the wireless service network after the network accessing routine of the BIOS memory 18 is executed. For example, the portable computer can be configured so that the LED is flickered in green color if the portable computer is accessible to the wireless service network; however, the LED is flickered in red color if a wireless access is not available. In addition, the portable computer may be configured so that the LED is flickered in orange color if a wireless accessing sensitivity is weak. The portable computer may also be configured so that the LED is flickered while the network accessing routine of the BIOS memory 18 is being executed. With these configurations, the user can confirm that the wireless LAN card 12 has determined/is checking whether the portable computer is accessible to the wireless service network.

According to an aspect of the present invention, the button part 16 is provided on an external surface of the body of the portable computer. Advantageously, according to the present invention the user can select whether to display the accessibility of the portable computer to the wireless communication service network through the button part 16 while the system power is turned off. In particular, typically, operation of the button part 16 activates the microcomputer 20 by allowing the power supplying part 10 to supply power to the microcomputer 20, and the microcomputer 20 controls the power supply to required/select portable computer components determining a wireless network accessibility status (state). If the button part 16 comprises a push button, it is possible to select and deselect (release), respectively, displaying the accessibility to the wireless service network by pressing or releasing the button part 16.

The microcomputer 20 controls the power supplying part 10 to allow driving power to be supplied to a series of portable computer system components, typically, comprising the wireless LAN card 12, the BIOS memory 18, and the displaying part 14, and to execute the network accessing routine of the BIOS memory 18, in response to the user selection to display the accessibility to the wireless service network through the button part 16 while the system power is turned off. The series of system components refers to a part of the portable computer system components required for displaying the accessibility to the wireless communication service network.

If the network accessing routine is executed, the wireless LAN card 12 is requested to check a level of a wireless signal received from an access point and determines whether the portable computer is accessible to the wireless communication service network according to the wireless signal level. A result of the determination is transmitted to the microcomputer 20 through the BIOS (i.e., the network accessing routine) and the microcomputer 20 supplies a control signal to the displaying part to display the accessibility to the wireless communication service network. In this regard, it is possible to determine the accessibility to the wireless communication service network at the BIOS level before the O/S booting, while the system power is turned off, according to a selection to display the accessibility to the wireless service network through a selection part.

If determined that a predetermined period of time has passed since selection of displaying the wireless network accessibility through the button part 16, the microcomputer 20 controls the power supplying part 10 to interrupt power supply to the series of system components displaying the wireless network accessibility, such as the wireless LAN card 12, the BIOS memory 18, and the displaying part 10. Typically, the predetermined period of time refers to a time lapse since displaying the wireless accessibility through the displaying part 14, after a selection of displaying the wireless accessibility through the button part 16. Accordingly, because the power supply can be automatically interrupted after activating a determination of the wireless accessibility, power consumption can be reduced.

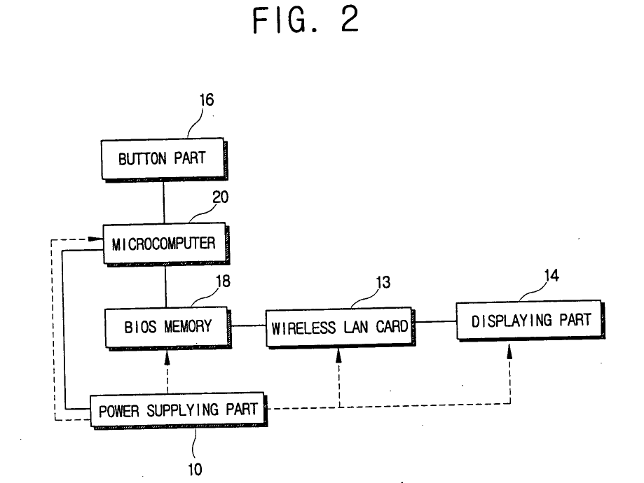

FIG. 2 is a control block diagram of a portable computer, according to another embodiment of the present invention. Description of the components having the same functions as those shown in FIG. 1 will be omitted, and only the wireless LAN card 12 and the microcomputer 20 specific to this figure will be described. In FIG. 2, a response to the selection to display the accessibility to the wireless service network through the button part 16, the microcomputer 20 controls the power supplying part 10 to allow driving power to be supplied to the series of system components comprising the wireless LAN card 12, the BIOS memory 18, the displaying unit 14, and executes the network accessing routine of the BIOS memory 18. Then, the wireless LAN card checks a level of the signal received at an access point and determines whether the portable computer is available for accessing the wireless communication service network according to the signal level.

After determining the wireless accessibility, in contrast to the portable computer of FIG. 1, the wireless LAN card 12 controls the displaying part 14 according to a result of the determination to display the wireless accessibility. Accordingly, the wireless LAN card 12 comprises firmware to control the displaying part 14.

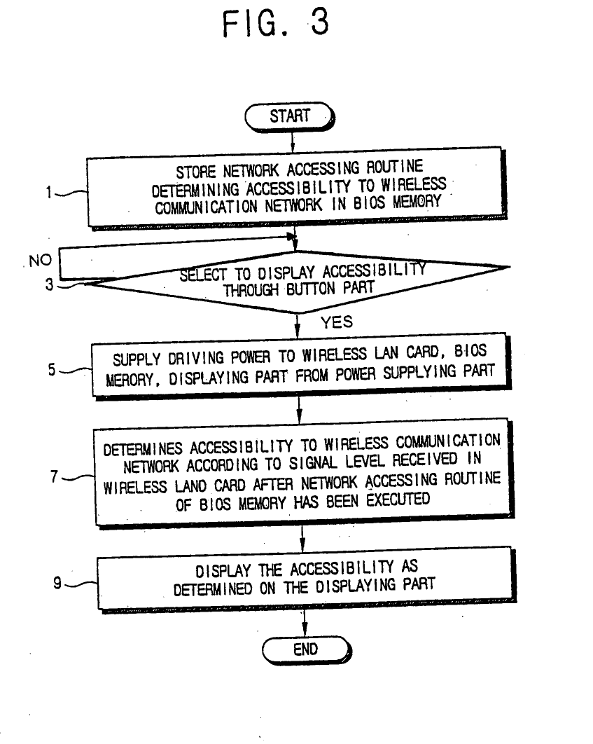

FIG. 3 is a flow chart of controlling the portable computers shown in FIGS. 1 and 2, according to an embodiment of the present invention. In FIG. 3, at operation 1, the network accessing routine is stored in the BIOS memory 18, wherein upon execution by the microcomputer 20, the network accessing routine determines the accessibility to the wireless communication service network by requesting the wireless LAN card 12 to determine the wireless accessibility based on a wireless signal received through the antenna of the wireless LAN card 12. If, at operation 3, it is determined that displaying the accessibility to the wireless service network is selected through the button part 16 while the power is turned off, at operation 5, the microcomputer 20 is powered controlling the power supplying part 10 to supply driving power to the series of system components comprising the wireless LAN card 12, the BIOS memory 18, and the displaying part 14. If, at operation 3, it is determined that displaying a wireless accessibility has not been selected, the portable computer system continues to monitor the button part 16 activation to select displaying the wireless accessibility. At operation 7, the microcomputer 20 executes the network accessing routine stored in the BIOS memory 14. In particular, at operation 7, the network accessing routine requests the wireless LAN card 12 to check a level of the wireless signal received from an access point through the antenna and the wireless LAN card 12 determines the accessibility to the wireless communication network based on the received signal level. If, at operation 9, the wireless accessibility determination is completed, the accessibility to the wireless communication service network is displayed through the displaying part 14.

According to the present invention, a result of the wireless accessibility determination by the wireless LAN card 12 can be transmitted to the microcomputer 20 through the BIOS, and the microcomputer 20 controls the displaying part 14 to display the result of the accessibility to the wireless communication service network, or otherwise the wireless LAN card 12 may directly control the displaying part 14.

Accordingly, the accessibility to the wireless communication service network can be determined at the BIOS level before the O/S booting while the system power is turned off. As described above, according to the present invention, there has been provided a portable computer wherein the availability for connecting to the wireless service network can be ascertained before the O/S booting, while the system power is turned off, thereby reducing the power consumption. More particularly, the present invention provides a portable computer, comprising a hardware selector operable while power to the portable computer is turned off; and a controller (e.g., a programmed computer processor) activated by operation of the selector and controlling a power supply (i.e., activate) only to portable computer components providing a wireless network accessibility state. Typically, the activated portable computer components comprise a wireless communication part receiving and transmitting a wireless signal through the wireless network, a BIOS memory storing a network accessing routine determining the wireless network accessibility state based upon the wireless signal received by the wireless communication part, and a notifying part, such as a displaying part, speaker, etc., providing the determined wireless accessibility state by displaying and/or audibly announcing the determined wireless accessibility state. Accordingly, the present invention provides a method of controlling a wireless portable computer, comprising storing in a BIOS memory of the computer a wireless network accessing routine providing a wireless network accessibility status, operating a hardware selector (e.g., a button, a switch, other input units) while power to the computer is turned off to supply power to the BIOS memory; and executing the wireless network accessing routine at the BIOS level (i.e., not executing the wireless network accessing routine at the operating system level or executing the wireless network accessing routine without starting/completing a POST booting and/or the OS booting) to provide the wireless network accessibility status, in response to the power supply from the hardware selector. The processes of the present invention as embodied in the controller and the portable computer components are implemented in software and/or computing hardware.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A portable computer including a power supplying part and a wireless communication part receiving and transmitting a wireless signal through a wireless communication service network, comprising:
a displaying part;
a selection part to select displaying a wireless accessibility to the wireless service network;
a BIOS memory storing a network accessing routine determining the wireless accessibility based on the wireless signal received by the wireless communicating part; and
a controller controlling the power supplying part to supply power to the displaying part, the wireless communication part and the BIOS memory to execute the network accessing routine, according to the selection to display the wireless accessibility through the selection part while the power to the portable computer is turned off, and controlling the displaying part to display the wireless accessibility.

2. The portable computer according to claim 1, wherein if determined that a predetermined period of time has passed since the displaying of the wireless accessibility was selected through the selection part, the controller controls the power supplying part to interrupt the power supply to the displaying part, the wireless communication part and the BIOS memory.

3. A method of controlling a portable computer including a power supplying part and a wireless communication part receiving and transmitting a wireless signal through a wireless communication service network, comprising:
storing in a BIOS memory, beforehand, a network accessing routine determining a wireless accessibility to the wireless service network based on a wireless signal received by the wireless communication part;
selecting to display the wireless accessibility to the wireless service network while the power to the portable computer is turned off;
supplying power to a displaying part, the wireless communication part, and the BIOS memory from the power supplying part, according to the selecting;
executing the network accessing routine of the BIOS memory, in response to the power supply; and
displaying the wireless accessibility as a result of executing the network accessing routine.

4. The method according to claim 3, further comprising controlling the power supplying part to interrupt the power supply to the displaying part, the wireless communication part and the BIOS memory, if determined that a predetermined period of time has passed since the displaying of the wireless accessibility was selected through the selection part.

5. A portable computer, comprising:
a hardware selector operable while power to the portable computer is turned off; and
a programmed computer processor activated by operation of the selector and controlling a power supply only to components providing a wireless network accessibility state.

6. The portable computer of claim 5, wherein the components comprise:
a wireless communication part receiving and transmitting a wireless signal through the wireless network;
a BIOS memory storing a network accessing routine determining the wireless network accessibility state based upon the wireless signal received by the wireless communication part; and
a notifying part providing the determined wireless accessibility state by displaying and/or audibly announcing the determined wireless accessibility state.

7. The portable computer of claim 5, wherein the components comprise:
a BIOS memory storing a network accessing routine; and
a wireless communication part receiving and transmitting a wireless signal through the wireless network to determine the wireless network accessibility state, in response to the network accessing routine, and providing the determined wireless accessibility state by displaying and/or audibly announcing the determined wireless accessibility state.

8. A portable computer controller, comprising:
a programmed computer processor operable according to a selector activation while a power supply to the portable computer is turned off and controlling the power supply only to portable computer components providing a wireless network accessibility state.

9. The controller of claim 8, wherein the portable computer components comprise:
a wireless communication part receiving and transmitting a wireless signal through the wireless network;
a BIOS memory storing a network accessing routine determining the wireless network accessibility state based upon the wireless signal received by the wireless communication part; and
a notifying part providing the determined wireless accessibility state by displaying and/or audibly announcing the determined wireless accessibility state.

10. The controller of claim 8, wherein the portable computer components comprise:
a BIOS memory storing a network accessing routine; and
a wireless communication part receiving and transmitting a wireless signal through the wireless network to determine the wireless network accessibility state, in response to the network accessing routine, and providing the determined wireless accessibility state by displaying and/or audibly announcing the determined wireless accessibility state.

11. A method of controlling a wireless portable computer, comprising:
storing in a BIOS memory of the wireless portable computer a wireless network accessing routine that provides a wireless network accessibility status;
operating a hardware selector while power to the computer is turned off to supply power to the BIOS memory; and
executing the wireless network accessing routine at the BIOS level to provide the wireless network accessibility status, in response to the operating of the hardware selector.
